(19) United States
(12) Patent Application Publication
(10) Pub. No.: US 2007/0158307 A1
(43) Pub. Date: Jul. 12, 2007

(54) Method for selective etching

(75) Inventors: Harald Kraus, Villach (DE); Martine Claes, Bertem (BE)

Correspondence Address: YOUNG & THOMPSON, 745 SOUTH 23RD STREET, 2ND FLOOR, ARLINGTON, VA, 22202, US

(73) Assignee: SEZ AG, Villach (AT)

(21) Appl. No.: 10/588,766

(22) PCT Filed: Feb. 7, 2005
(86) PCT No.: PCT/EP05/50510

§ 371 Date: Aug. 8, 2006

(30) Foreign Application Priority Data
Feb. 11, 2004 (AT) A 212/2004

(51) Int. Cl. B44C 1/22; H01L 21/302; C23F 1/00

(52) U.S. Cl. 216/83; 438/745; 216/99

(57) ABSTRACT

Disclosed is a method of selective etching a first material on a substrate with a high selectivity towards a second material by flowing a liquid etchant across a substrate surface at a flow sufficient fast to generate a minimum mean velocity v parallel to the substrate's surface.

The invention relates to a method of selective etching a first material on a substrate with a high selectivity towards a second material.

Such a selective etching can be used in semiconductor device manufacturing process or e.g. in producing flat panel displays. Hence said substrate may be a semi-conductor wafer or a flat panel display.

The process may be used for successful integration of gate stacks comprising dielectric materials with a high dielectric constant (high-k dielectrics). As disclosed in US2003/0109106A1 examples of high-k dielectrics include silicates, aluminates, titanates, and metal oxides. Examples of silicate high-k dielectrics include silicates of Ta, Al, Ti, Zr, Y, La and Hf, including metal-doped silicon oxides (e.g. with Zr and Hf) and silicon oxynitrides. Examples of aluminates include refractory metal aluminates, such as compounds of Zr and Hf, and aluminates of Lanthanide series metals, such as La, Lu, Eu, Pr, Nd, Gd, and Dy. Examples of titanate high-k dielectrics include BaTiO₃, SrTiO₃, and PdZrTiO₃. Examples of metal oxide high-k dielectrics include oxides of refractory metals, such as Zr and Hf, and oxides of Lanthanide series metals, such as La, Lu, Eu, Pr, Nd, Gd, and Dy. Additional examples of metal oxide high-k dielectrics include Al₂O₃, TiO₂, Ta₂O₅, Nb₂O₅ and Y₂O₃.

The high-k dielectric is generally formed in a layer over a substrate with islands of oxide insulator. The high-k dielectric layer is formed by any suitable process, such as spin coating, chemical vapor deposition (e.g. atomic layer deposition=ALD), physical vapor deposition, molecular beam epitaxy or mist deposition. Generally, prior to etching, the high-k dielectric forms a continuous layer over the substrate. In one embodiment, the layer is from about 1 nm to about 100 nm thick. In another embodiment, the layer is from about 3 nm to about 50 nm thick. In a further embodiment, the layer is from about 2 nm to about 30 nm thick.

For example hafnium oxide (HfO₂) can be deposited on the substrate through atomic-layer chemical vapor deposition (ALCVD=atomic-layer deposition=ALD) (US2003/0230549A1). To achieve a merely crystalline structure of said hafnium oxide the substrate is thermally treated (e.g. 550° C., 1 min). Such thermally treatment is called post deposition anneal (PDA).

As proposed in US2003/0230549A1 wet etching selectivity of high-k dielectrics can be enhanced through a pretreatment with plasma-based ion bombardment. This is merely because the respective dielectric material if highly crystalline is almost impossible to etch with liquid etchants. Thus the damage of the crystalline structure is proposed.

Wet etching of such pretreated dielectrics is disclosed in “Selective Wet Etching of Hf-based Layers”, M. Claes et.al. IMEC-UCP-IIAP Chapter 3, presented at ECS Fall Meeting, Orlando, Fla., October 2003. High efforts have been made to optimize the etching liquid to increase selectivity. Proposed etchants comprise hydrofluoric acid and an acid to achieve low pH (<3) and/or an alcohol to achieve a low dielectric constant. Preferred etchants comprise hydrofluoric acid and both an acid and an alcohol.

An object of the invention is to provide a method for etching a first material (e.g. high-k dielectric) on a substrate with a high selectivity towards a second material (e.g. silicon dioxide (e.g. TEOS (tetra ethoxysilane ), ThOx (thermal oxide)), silicon (e.g. bulk silicon, polycrystalline silicon))

Another object of the invention is to provide selectivity against all other materials especially insulating materials such as thermally produced silicon oxide (Thermal Oxide abbreviated THOX) and polycrystalline silicon (polysilicon).

The invention meets the objects by providing a method of selective etching comprising:
providing a first material selected from a group A on a substrate
providing a second material selected from a group B on a substrate
selectively etching said first material with a selectivity of at least 2:1 towards said second material by a liquid etchant flowing across the substrate surface at a flow sufficient fast to generate a mean velocity v parallel to the substrate's surface of minimum 0,1 m/s . A preferred velocity v is above 0,5 m/s

The first material is different from the second material either in chemical composition or crystalline structure or in both.

The minimum velocity can be generated with a closed flow as follows:
providing a plate substantially parallel to the substrate (wafer) and thereby generating a gap between said substrate and said plate with a gap distance d,
introducing said liquid etchant into the gap so that both the substrate surface (facing the plate) and the plate surface (facing the substrate) are wetted,
introducing said liquid etchant into the gap at a velocity v.

For a given cross sectional area (a) of the gap the necessary volume flow (Q) can be selected to achieve the minimum velocity. For instance a substrate diameter of 0,2 m (e.g. a 200 nm wafer) and a gap distance d=1 mm leads to a minimum volume flow of 2E-5 m³/s (=1,2 l/min).

Another possibility for generating a flow with minimum velocity across the wafer is to dispense the etchant onto the substrate with a free beam at such a minimum velocity. This is because liquid, which is dispensed as a free beam, is guided into a direction parallel to the substrate's surface substantially without any decrease of velocity. Liquid, which is dispensed as a free beam out of a nozzle with a velocity v₀, is further accelerated or decelerated depending on whether liquid is dispensed from above or from below onto the substrates surface according to the following equation, wherein vₐ is the velocity of the liquid when touching the wafer.

Liquid dispensed from above:
vₐ²=v₀²+2 gl

Liquid dispensed from below:
vₐ²=v₀²−2 gl

vₐ . . . velocity of the liquid when touching the wafer

v₀ . . . velocity of the liquid when leaving the dispensing nozzle

g . . . acceleration due to gravity

l . . . height difference between nozzle and surface of the substrate.

Liquid, which is dispensed onto a substrate through a free beam, has a flow in a shooting state when flowing across the substrate's surface. This is described by Froude Number of greater 1 (Fr=v²/(g*h); wherein v is the velocity of the liquid flowing across the substrate, g is the acceleration due to gravity and h is the height of the liquid film flowing across the substrate).

Surprisingly it was discovered that the selectivity of an etching process can be significantly increased by using the invented method compared to known selective etching processes where substrates are immersed into the etching liquid. Without being bound to any theory it is believed that the reason of the significant increase of the selectivity by the high velocity is a very thin diffusion layer and/or the fast transport of reaction products and/or by products away from the place of reaction.

In a preferred embodiment the liquid is dispensed onto the substrate in a continuous flow and spread over the substrate's surface. Such a continuous flow can be achieved through a media nozzle dispensing said liquid in a free beam.

Another embodiment uses a method wherein the point of impact of the liquid stream is moved across the surface of the substrate in a time sequence. The point of impact shall be defined as intersection between the surface of the substrate and the axis of the free beam of the liquid. If the substrate is rotated and the liquid is dispensed through a nozzle on a media arm said point of impact will be moved by moving the media arm across the substrate. This moving of the point of impact results in a better uniformity.

Although the velocity is not primarily depending on the volume flow a minimum flow is useful in order to evenly cover the substrate when liquid is dispensed on it. A volume flow of at least 0,05 l/min (especially at least 0,5 l/min) is preferred.

Rotating said substrate while being exposed to said liquid etchant helps to keep the necessary minimum velocity of the liquid on the substrate. This could be necessary if the liquid is dripped onto the substrate. Another advantage for rotating said substrate is to fling the liquid off the substrate. Thus the liquid might be collected by a surrounding bowl and recycled. It is preferred to rotate the substrate at a spin speed of more than 100 revolutions per minute (rpm) especially more than 300 rpm.

In a preferred method the abovementioned group A comprises materials with a high dielectric constant (high-k material) e.g. metal oxides (e.g. hafnium oxide, zirconium oxide, Zr_{z}Hf_{y}Oₓ) or silicates (e.g. Zr_{z}Si_{y}Oₓ, Hf_{z}Si_{y}Oₓ) or aluminates (e.g. Hf_{z}Al_{y}Oₓ, and Zr_{z}Al_{y}Oₓ) or other materials as mentioned above.

Group B preferably comprises silicon dioxide (e.g. TEOS, ThOx), silicon (e.g. bulk silicon, polycrystalline silicon). The method according to the invention is especially useful for etching a first material selectively towards silicon dioxide especially when a liquid etchant comprising fluoride ions is used.

In order to further enhance selectivity said first material is subjected a pretreatment in order to damage the material's structure. This might be necessary, if the material has a merely crystalline structure due to a previous annealing step.

Such pretreatment may be an energetic particle bombardment—e.g. an ion bombardment with species such as Si, Ge, B, P, Sb, As, O, N, Ar, BF₃.

Yet another preferred embodiment of the method uses liquid etchant, which is selected from a group comprising:
a solution comprising fluoride ions and an additive for lowering dielectric constant of said solution e.g. an alcohol,
an acidic, aqueous solution comprising fluoride ions.
an acidic, aqueous solution comprising fluoride ions and an additive for lowering dielectric number e.g. an alcohol.

Said liquid etchant may comprise fluoride ions and has a pH value of below 3. A pH value of below 2 is preferred. To achieve such a pH value strong inorganic acids, such as hydrochloric acid, sulfuric acid, phosphoric acid or nitric acid are well known in the art. This is to suppress the building of HF₂⁻—anions.

A preferred liquid etchant comprises less than 0,1 mol/l of fluoride ions (analytical concentration, calculated as F⁻).

Further details and advantages of the invention can be realized from the drawings and detailed description of a preferred embodiment.

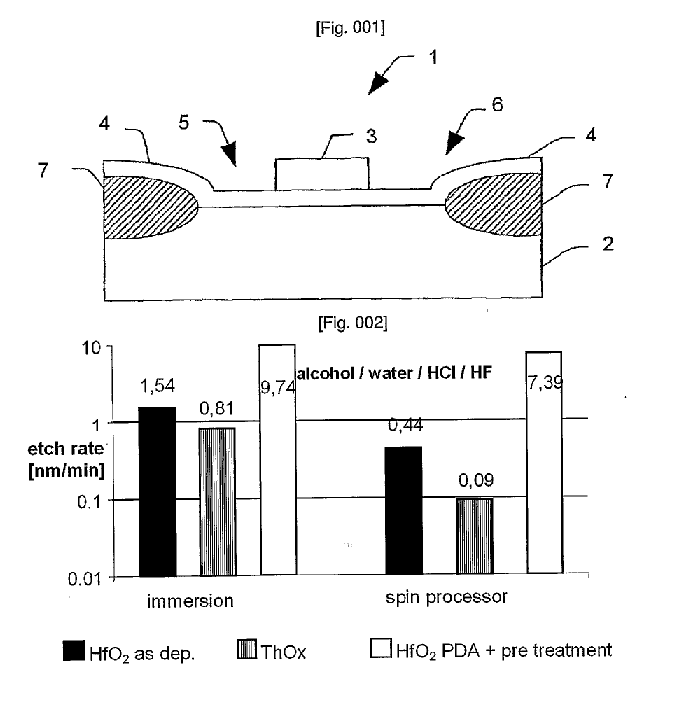

FIG. 1 shows a schematic drawing of a substrate to which a method of the invention can be applied.

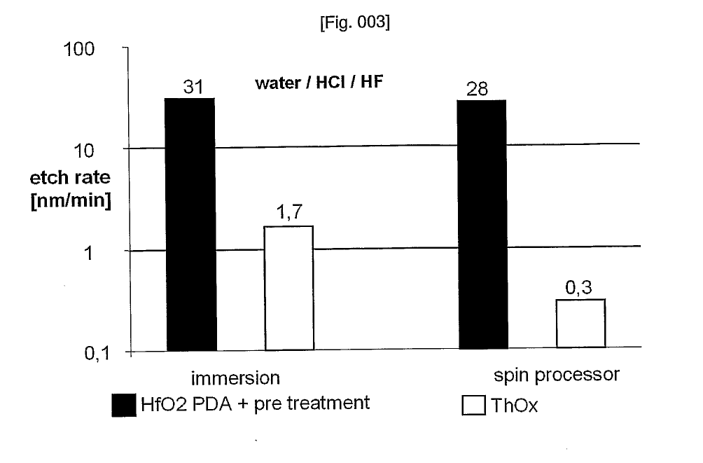

FIG. 2 and FIG. 3 show charts of etch rates for different materials comparing different methods.

A preferred embodiment of the method shall be described for selectively removing high-k material from the source and drain area of a FET. FIG. 1 shows a schematic drawing of a substrate during manufacture FET using high-k material. FET 1 is manufactured on bulk silicon 2 with field oxide islands 7 (e.g. ThOx), high-k material (e.g. HfO₂) 4 deposited on bulk silicon 2 and field oxide islands and a polysilicon layer 3 on the high-k material. The polysilicon layer has been patterned to provide gaps for source area 5 and drain area 6. The high-k material has to be removed from the source and drain area 5 and 6 and above the field oxide 7 islands without affecting the polysilicon layer 3 or the field oxide islands 7.

Studies have been made to compare etch rate of different materials using different etching techniques. FIG. 2 shows a chart of etch rates of different materials, which are (1) HfO₂ as deposited, (2) HfO₂ with post deposition anneal (PDA) and pre treatment before etch (ion bombardment) and (3) thermal oxide. Different methods have been compared, which are immersion of the substrate in an etch bath and dispensing the etchant in a continuous flow (free beam) onto a rotating wafer (900 rpm) in a spin processor. The etchant is a composition comprising an acohol, HCl and HF. For all experiments a temperature of 55° C. has been used.

As can be seen on the chart of FIG. 2, etch rate of HfO₂ and ThOx decreases when using a high flow across the substrate. Whereas the etch rate of annealed and pretreated HfO₂ decreases only by a factor 1,3 the etch rate of ThOx decreases by a factor 9. The etch rate of HfO₂ even just as deposited decreased only by a factor 3,5. Hence the etch selectivity of HfO₂ (annealed and pretreated) towards ThOx increased from 12:1 to 88:1. This improvement of selectivity of a factor 7 is extraordinary, when keeping temperature and composition of the etchant unchanged.

In another embodiment a mixture of water, HCl (2,4 mol/l) and HF (0,05 mol/l) was used, again at 55° C. The chart in FIG. 3 shows again a decrease of the etch rate of HfO₂ and ThOx when using a high flow across the substrate. The etch selectivity of HfO₂ (annealed and pretreated) towards ThOx increased from 18:1 (immersed in an etching bath) to 93:1 (using a high flow across the substrate in a spin processor).

1. Method of selective etching comprising:
providing a first material selected from a group A on a substrate
providing a second material selected from a group B on a substrate
selectively etching said first material with a selectivity of at least 2:1 towards said second material by a liquid etchant flowing across the substrate surface at a flow sufficient fast to generate a mean velocity v parallel to the substrate's surface of minimum 0,1 m/s

2. Method of claim 1 wherein said liquid is dispensed onto the substrate in a continuous flow and spread over the substrate's surface

3. Method of claim 2 wherein the point of impact of the liquid stream is moved across the surface of the substrate in a time sequence.

4. Method of claim 2 wherein said liquid is dispensed at a volume flow of at least 0,05 l/min (especially at least 0,5 l/min).

5. Method of claim 1 wherein said substrate is rotated while exposed to said liquid etchant.

6. Method of claim 1 wherein group A comprises materials with a high dielectric constant.

7. Method of claim 1 wherein group B comprises silicon dioxide, silicon.

8. Method of claim 1 wherein the second material is silicon dioxide and the liquid etchant comprises fluoride ions.

9. Method of claim 1 wherein said first material is subjected a pretreatment in order to damage the material's structure.

10. Method of claim 9 wherein said pretreatment is an energetic particle bombardment.

11. Method of claim 1 wherein said liquid etchant is selected from a group comprising
a solution comprising fluoride ions and an additive for lowering dielectric constant of said solution,
an acidic, aqueous solution comprising fluoride ions.
an acidic, aqueous solution comprising fluoride ions and an additive for lowering dielectric number e.g. an alcohol.

12. Method of claim 11 wherein said liquid etchant comprises an analytical concentration of less than 0,01 mol/l of fluoride ions, wherein said analytical concentration is calculated as F⁻.

13. Method of claim 1 wherein said liquid etchant comprises fluoride ions and has a pH value of below 3.
